(19) United States
(12) Patent Application Publication
(10) Pub. No.: US 2014/0009192 A1
(43) Pub. Date: Jan. 9, 2014

(54) CLOCK GENERATION CIRCUIT AND METHOD FOR CONTROLLING CLOCK GENERATION CIRCUIT

(71) Applicant: FUJITSU LIMITED, Kawasaki-shi (JP)

(72) Inventor: Kouichi SUZUKI, Kawasaki (JP)

(73) Assignee: FUJITSU LIMITED, Kawasaki-shi (JP)

(21) Appl. No.: 14/024,462

(22) Filed: Sep. 11, 2013

Related U.S. Application Data
(63) Continuation of application No. PCT/JP2011/056855, filed on Mar. 22, 2011.

(51) Int. Cl. H03L 7/18

(52) U.S. Cl. CPC H03L 7/18
USPC 327/115

(57) ABSTRACT

A PLL generates an output clock obtained by multiplying a reference clock by an odd number. An odd-number frequency divider divides the output clock by the odd number to generate a first clock. A frequency divider divides the first clock by a predetermined number to generate a second clock. An even-number frequency divider divides the output clock by an even number to generate a third clock. A frequency divider divides the third clock at such a frequency division ratio that makes the frequency division ratio of the odd-number frequency divider and the frequency divider match the frequency division ratio of the even-number frequency divider and the frequency divider to generate a fourth clock. A control unit lowers an oscillation frequency of the PLL when the result of comparing the second clock and the fourth clock represents a mismatch.

### CROSS-REFERENCE TO RELATED APPLICATION

This application is a continuation of International Application No. PCT/JP2011/056855, filed on Mar. 22, 2011, the entire contents of which are incorporated herein by reference.

### FIELD

The embodiments discussed herein are related to a clock generation circuit and a method for controlling the clock generation circuit.

### BACKGROUND

Generally, a phase lock loop (PLL) circuit is a clock generation circuit used for generating a clock by multiplying a reference clock. The following describes a procedure for generating a clock by the PLL circuit. First, the PLL circuit receives an input of the reference clock. The PLL circuit divides a high frequency clock that is an output of a voltage controlled oscillator (VCO) using a frequency divider, and generates a frequency divided clock corresponding to a predetermined multiplication ratio. Then, the PLL circuit compares the reference clock with the frequency divided clock using a phase frequency detector (PFD). Next, the PLL circuit converts an error signal output from the phase frequency director to an analog signal, and removes an unnecessary signal. Then the PLL circuit controls an oscillation frequency of the VCO using the error signal so that the frequencies and the phases of the reference clock and the frequency divided clock are the same. Accordingly, the PLL circuit generates a clock output from the VCO as a desired multiplied clock.

In some PLL circuits that input a high-frequency signal output from the VCO, a plurality of frequency dividers having different frequency division ratios are arranged in parallel. The PLL circuit selects an output having an appropriate frequency divided clock from among outputs from the frequency dividers by a selector, and outputs it to a subsequent stage. For example, in the PLL circuit using a plurality of numbers of multiplication such as 4 and 5, frequency dividers of 4-division and 5-division are connected in parallel to the output from the VCO. Such a PLL circuit selects a frequency divider having a frequency division ratio to be used from the above frequency dividers on the basis of an external setting.

The upper limit for operating frequency by which the frequency divider normally operates is generally higher than a frequency of a circuit on which the PLL circuit is mounted. This is because in a pull-in process at an initial training in the PLL circuit, the oscillation frequency of the VCO fluctuates and converges to a steady operating frequency of a circuit mounted on the PLL circuit. The “pull-in process” indicates a process in which the PLL circuit starts to operate and an input signal and an output signal are synchronized with each other and stabilized, for example.

The PLL circuit only compares phases of the reference clock and the frequency divided clock, so that it is difficult to detect a synchronization error caused by malfunction of the frequency divider. Therefore, the upper-limit frequency at which the frequency divider connected to a VCO output operates is acceptable to be equal to or higher than a VCO oscillation frequency that is higher than an operating frequency of a circuit on which the PLL is mounted so that the PLL circuit is not erroneously synchronized.
Patent Document 1: Japanese Laid-open Patent Publication No. 09-205364

However, in recent years, the operating frequency of the circuit on which the PLL circuit is mounted has been increasing to satisfy indications such as to increase the number of multiplication and to increase the reference clock frequency in order to cause a system to quickly operate. In this way, a circuit operation margin in the PLL decreases because the operating frequency of the circuit on which the PLL circuit is mounted increases. Accordingly, the frequency divider uses a larger operation margin when pulling-in the PLL than that in a steady operation in the PLL circuit, and hence there is a risk such as it is difficult to sufficiently secure a margin and the operation becomes unstable.

The operating frequency of the frequency divider is determined with reference to a frequency at the time when the clock is accelerated more than a setup time and a hold time of a flip flop (FF) and an output of the FF does not catch up with an input clock. As compared with the frequency divider having an even number frequency division ratio that directly inputs the FF output to the FF, the frequency divider having an odd number frequency division ratio that inputs a plurality of FF outputs to the FF through a logic circuit using the FF outputs as an input takes more time corresponding to delay time of the logic circuit. Therefore, the frequency divider having the odd number frequency division ratio only operates at a clock having a period longer than that of the frequency divider having the even number frequency division ratio. Accordingly, the operating frequency of the frequency divider having the odd number frequency division ratio is lower than that of the frequency divider having the even number frequency division ratio.

When the operating frequency increases, the output of the frequency divider having the odd number frequency division ratio fails to be inverted earlier than the frequency divider having the even number frequency division ratio fails, among the frequency dividers influenced by variation in the oscillation frequency of the VCO. In this case, the frequency divider having the odd number frequency division ratio causes malfunction such as the outputting of a clock having a high frequency division ratio, that is, a clock having a low frequency.

As a result, the frequency divided clock, which is compared with the reference clock, is locked higher than expected with a desired frequency division ratio. That is, the PLL circuit performs erroneous synchronization leaving the VCO oscillation frequency set to a clock frequency higher than expected with a desired number of multiplication. Therefore, it has been difficult to apply an operating frequency substantially the same as that in the PLL circuit including the frequency divider having the even number frequency division ratio to the PLL circuit including the frequency divider having the odd number frequency division ratio.

### SUMMARY

According to an aspect of an embodiment, a clock generation circuit includes: a phase lock loop (PLL) that generates an output clock obtained by multiplying a reference clock by an odd number of multiplication; a first frequency divider circuit that divides the output clock by the odd number to generate a first frequency divided clock; a second frequency divider circuit that divides the first frequency divided clock by a predetermined number to generate a second frequency divided clock; a third frequency divider circuit that divides the output clock by an even number to generate a third frequency divided clock; a fourth frequency divider circuit that divides the third frequency divided clock at such a frequency division ratio that makes a frequency division ratio of the first frequency divider circuit and the second frequency divider circuit match a frequency division ratio of the third frequency divider circuit, to generate a fourth frequency divided clock; a comparator circuit that compares phases or frequencies of the second frequency divided clock and the fourth frequency divided clock; and a control circuit that performs control of lowering an oscillation frequency of the PLL when the comparison result by the comparator circuit represents a mismatch.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating a clock generation circuit according to a first embodiment;

FIG. 2 is a figure of the principle of a frequency divider and an erroneous frequency division detector according to the first embodiment;

FIG. 3 is a schematic diagram illustrating the frequency divider and the erroneous frequency division detector according to the first embodiment when n=m=2;

FIG. 4 is a diagram illustrating an example of a frequency detector;

FIG. 5A is an example of a timing chart of each clock in a normal operation;

FIG. 5B is an example of a timing chart of each clock when malfunction occurs;

FIG. 6 is a block diagram illustrating a control unit according to the first embodiment;

FIG. 7 is a diagram illustrating a range of frequency adjustment by a VCO for each frequency offset;

FIG. 8 is a diagram illustrating the adjustment of an oscillation frequency by changing the frequency offset in a normal operation;

FIG. 9 is a diagram illustrating the adjustment of the oscillation frequency by changing the frequency offset when malfunction occurs;

FIG. 10 is a flow chart of a process of initial training in the clock generation circuit according to the first embodiment;

FIG. 11 is a figure of the principle of a frequency divider and an erroneous frequency division detector according to a second embodiment;

FIG. 12 is a block diagram illustrating a clock generation circuit according to a third embodiment; and

FIG. 13 is a schematic diagram illustrating a frequency divider and a frequency divider circuit according to the third embodiment.

### DESCRIPTION OF EMBODIMENTS

referred embodiments of the present invention will be explained with reference to accompanying drawings. The clock generation circuit and the method for controlling the clock generation circuit disclosed herein are not limited by the embodiments below.

### [a] First Embodiment

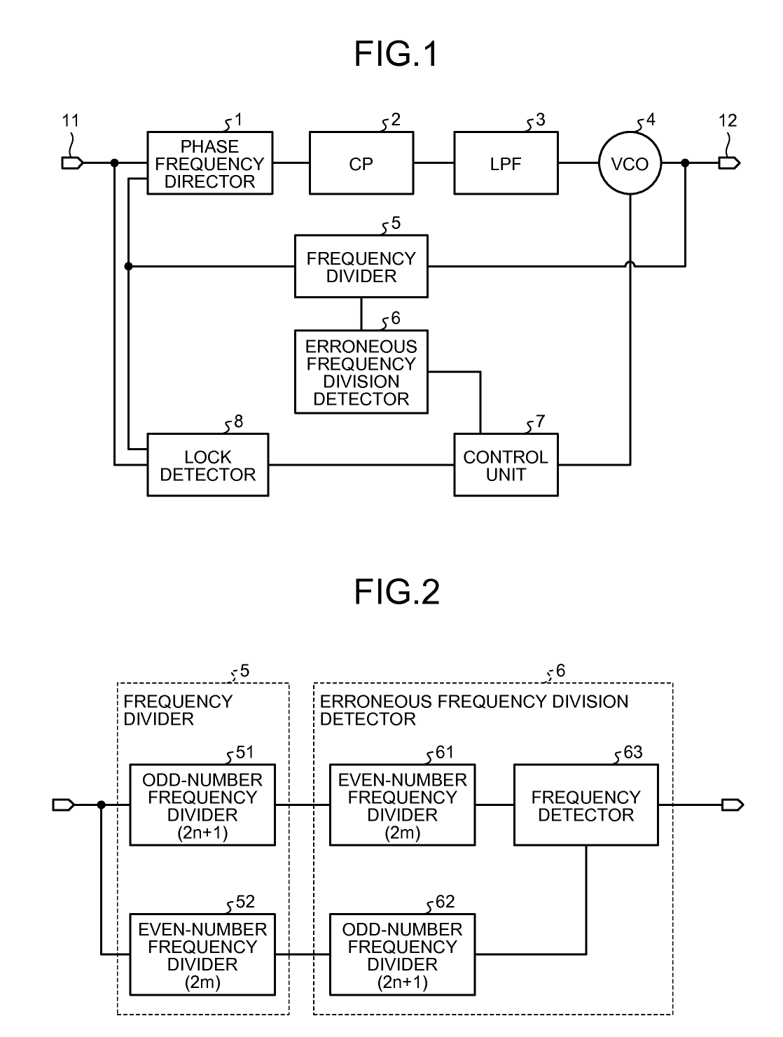

FIG. 1 is a block diagram illustrating a clock generation circuit according to a first embodiment. The clock generation circuit according to the first embodiment includes a phase frequency director (PFD) 1, a charge pump (CP) 2, a low pass filter (LPF) 3, a VCO 4, a frequency divider 5, an erroneous frequency division detector 6, a control unit 7, a lock detector 8, an input terminal 11, and an output terminal 12. The phase frequency director 1, the CP 2, the LPF 3, the VCO 4, and the frequency divider 5 compose an example of the PLL.

The phase frequency director 1 receives a reference clock input to the input terminal 11 from outside. The phase frequency director 1 also receives, from the frequency divider 5, an input of a clock obtained by dividing an output clock output from the VCO 4 to be described later (hereinafter, referred to as a “frequency divided clock” in some cases).

The phase frequency director 1 detects a phase difference and a frequency difference between the reference clock and the frequency divided clock. Next, the phase frequency director 1 generates an error signal from the detected phase difference and frequency difference. Then the phase frequency director 1 outputs the generated error signal to the CP 2.

The CP 2 receives an input of the error signal from the phase frequency director 1. Then the CP 2 converts the input error signal into an analog signal from a digital signal. The CP 2 boosts the voltage of the error signal. The CP 2 outputs the error signal converted into the analog signal to the LPF 3.

The LPF 3 receives an input of the error signal converted into the analog signal, from the CP 2. The LPF 3 blocks a high frequency component of the input error signal and rectifies the signal. Then the LPF 3 outputs the generated direct current voltage to the VCO 4.

The VCO 4 receives, from the LPF 3, an input of the direct current voltage generated from the error signal. For example, if the phase of the frequency divided clock is ahead of that of the reference clock, a positive voltage corresponding to the degree of the difference therebetween is input to the VCO 4. If the phase of the frequency divided clock is behind that of the reference clock, a negative voltage corresponding to the degree of the difference therebetween is input to the VCO 4. The oscillation frequency of the VCO 4 is controlled by the input voltage so that the phases and the frequencies of the reference clock and the frequency divided clock match each other. Then the VCO 4 outputs a clock having the oscillation frequency (hereinafter, also referred to as an “output clock” in some cases) through the output terminal 12. The VCO 4 also outputs the output clock to the frequency divider 5.

For example, at the time of initial training, the VCO 4 receives an input of a control code for adjusting an frequency offset from the control unit 7 to be described later. The following describes the control code for adjusting the frequency offset. The VCO 4 can control the oscillation frequency in a specific frequency range with reference to a frequency designated by the control code. The control code provides a frequency offset for switching the range of the oscillation frequency of the VCO 4. When the frequency offset is changed by the control code, the VCO 4 controls the oscillation frequency in a range based on the changed frequency offset. That is, the control code for adjusting the frequency offset is a command to designate the range in which the frequency is controlled at the VCO 4.

The VCO 4 changes its own oscillation frequency corresponding to the received control code. For example, when receiving the control code using a frequency offset one-step lower than the frequency offset being used, the VCO 4 controls the oscillation frequency in a one-step lower range. For example, when a binary code for controlling the VCO 4 is assigned to each frequency offset, the VCO 4 is instructed to lower the oscillation frequency by receiving an input of the binary code designating the one-step lower frequency offset. At the time of activation of the clock generation circuit, the VCO 4 receives an input of a control code providing a frequency offset having a middle value of the frequency offsets provided by control codes from the control unit 7 as described later, in the first embodiment. Then the VCO 4 operates at the range of the oscillation frequency corresponding to the received control code, oscillates at an initial frequency within the range, and outputs the output clock having the initial frequency.

As described above, the VCO 4 can pull in the PLL again even in a locked state of erroneous synchronization because the frequency offset is changed, so that the locked state may be cancelled. Then the VCO 4 can control the output clock so that the frequency divided clock divided at a predetermined odd multiple ratio is equal to the reference clock. Accordingly, the VCO 4 may cause the reference clock and the frequency divided clock to be correctly synchronized.

Next, the frequency divider 5 and the erroneous frequency division detector 6 will be described. FIG. 2 is a figure of the principle of the frequency divider and the erroneous frequency division detector according to the first embodiment. As illustrated in FIG. 2, the frequency divider 5 includes an odd-number frequency divider 51 that divides the output clock at an odd number frequency division ratio (2n+1) and an even-number frequency divider 52 that divides the output clock at an even number frequency division ratio (2m). Each of n and m is an integer equal to or larger than 1. The erroneous frequency division detector 6 includes an even-number frequency divider 61 that divides an input signal at the even number frequency division ratio (2m), an odd-number frequency divider 62 that divides an input signal at the odd number frequency division ratio (2n+1), and a frequency detector 63. In the first embodiment, the frequency division ratios of the odd-number frequency divider 51 and the odd-number frequency divider 62 have the same value (2n+1). In the first embodiment, the frequency division ratios of the even-number frequency divider 52 and the even-number frequency divider 61 have the same value (2m).

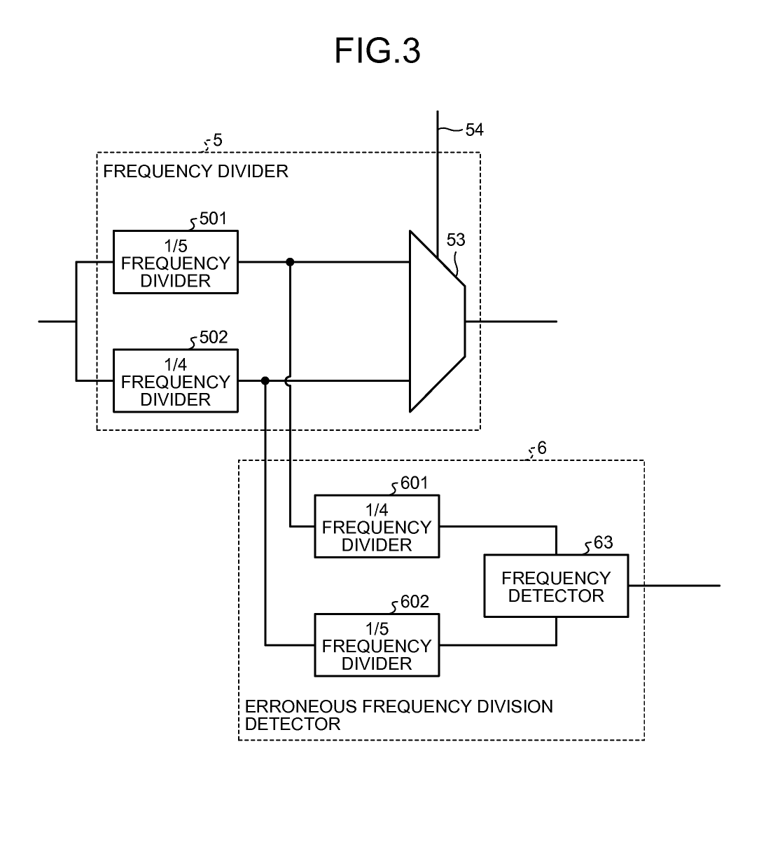

The following describes the frequency divider 5 and the erroneous frequency division detector 6 more specifically with reference to FIG. 3. FIG. 3 is a schematic diagram illustrating the frequency divider and the erroneous frequency division detector according to the first embodiment when n=m=2. The integers n and m may be any integer as long as it is an integer equal to or larger than 1. The first embodiment describes a case where n=m=2, that is, a case where the odd number frequency division ratio is 5 and the even number frequency division ratio is 4. As illustrated in FIG. 3, in the first embodiment, the frequency divider 5 includes a ⅕ frequency divider 501 as the odd-number frequency divider 51 and a ¼ frequency divider 502 as the even-number frequency divider 52. In the first embodiment, the frequency divider 5 also includes a selector 53 so that any one of a ⅕ frequency divided clock and a ¼ frequency divided clock may be output as a clock used for comparison with the reference clock.

The ⅕ frequency divider 501 receives an input of the output clock from the VCO 4. The ⅕ frequency divider 501 divides the received output clock by 5 and generates a frequency divided clock having a frequency five times that of the output clock. Then the ⅕ frequency divider 501 outputs the generated frequency divided clock to the selector 53. The ⅕ frequency divider 501 also outputs the generated frequency divided clock to a ¼ frequency divider 601 of the erroneous frequency division detector 6. The ⅕ frequency divider 501 is an example of a “first frequency divider circuit”.

The ¼ frequency divider 502 receives an input of the output clock from the VCO 4. The ¼ frequency divider 502 divides the received output clock by 4 and generates a frequency divided clock having a frequency four times that of the output clock. Then the ¼ frequency divider 502 outputs the generated frequency divided clock to the selector 53. The ¼ frequency divider 502 also outputs the generated frequency divided clock to a ⅕ frequency divider 602 of the erroneous frequency division detector 6. The ¼ frequency divider 502 is an example of a “third frequency divider circuit”.

An operator determines a frequency division ratio to be used and inputs a frequency division ratio selection control signal that gives an instruction to output a frequency divided clock having the determined frequency division ratio via a line 54 to the selector 53. The selector 53 then receives an input of the frequency division ratio selection control signal via the line 54.

The selector 53 receives the frequency divided clock having a frequency five times that of the output clock from the ⅕ frequency divider 501. The selector 53 also receives the frequency divided clock having a frequency four times that of the output clock from the ¼ frequency divider 502.

The selector 53 selects a frequency divided clock having the frequency division ratio designated by the frequency division ratio selection control signal. Then the selector 53 outputs the selected frequency divided clock to the phase frequency director 1. As described above, the frequency divider 5 according to the first embodiment can select any of the ⅕ frequency divided clock and the ¼ frequency divided clock to be used for comparison with the reference clock. Therefore, the clock generation circuit according to the first embodiment can generate a clock having a frequency four times the reference frequency and a clock having a frequency five times the reference frequency. In a configuration in which only the frequency divided clock from the odd-number frequency divider is used for comparison with the reference clock, an erroneous synchronization of the odd-number frequency divider can be detected.

Next, as illustrated in FIG. 3, the erroneous frequency division detector 6 includes the ¼ frequency divider 601 as the even-number frequency divider 61 and includes the ⅕ frequency divider 602 as the odd-number frequency divider 62.

The ¼ frequency divider 601 receives an input of the frequency divided clock obtained by dividing the output clock by 5 from the ⅕ frequency divider 501. Then the ¼ frequency divider 601 divides the received frequency divided clock by 4 and generates a frequency divided clock. That is, the ¼ frequency divider 601 generates a clock obtained by dividing the output clock by 5, and subsequently by 4 (hereinafter, also referred to as a “5×4 frequency divided clock” in some cases). Then the ¼ frequency divider 601 outputs the generated frequency divided clock to the frequency detector 63. The ¼ frequency divider 601 is an example of a “second frequency divider circuit”.

The ⅕ frequency divider 602 receives an input of the frequency divided clock obtained by dividing the output clock by 4 from the ¼ frequency divider 502. Then the ⅕ frequency divider 602 divides the received frequency divided clock by 5 and generates a frequency divided clock. That is, the ⅕ frequency divider 602 generates a clock obtained by dividing the output clock by 4, and subsequently by 5 (hereinafter, also referred to as a “4×5 frequency divided clock” in some cases). Then the ⅕ frequency divider 602 outputs the generated frequency divided clock to the frequency detector 63. The ⅕ frequency divider 602 is an example of a “fourth frequency divider circuit”.

The frequency detector 63 receives an input of the 5×4 frequency divided clock from the ¼ frequency divider 601. The frequency detector 63 receives an input of the 4×5 frequency divided clock from the ⅕ frequency divider 602. The frequency detector 63 determines whether malfunction is occurring based on the existence of a difference between a frequency of the 5×4 frequency divided clock and a frequency of the 4×5 frequency divided clock. The frequency detector 63 outputs a determination result to the control unit 7. The frequency detector 63 is an example of a “comparator circuit”.

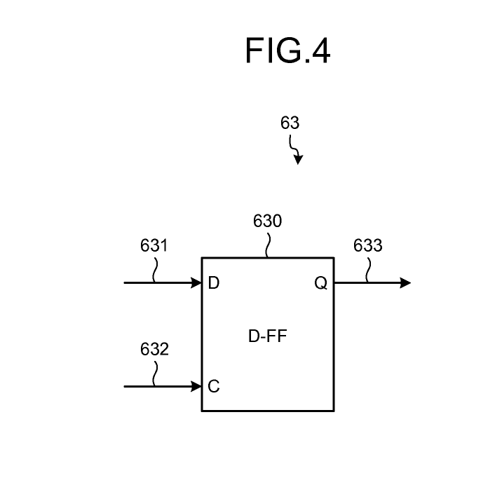

FIG. 4 is a diagram illustrating an example of the frequency detector. In the first embodiment, as illustrated in FIG. 4, a case where a D-type flip flop (D-FF) 630 is used for the frequency detector 63 will be described by way of example.

The 5×4 frequency divided clock is input as a D input 631 of the D-FF 630. The 4×5 frequency divided clock is input as a C input 632 of the D-FF 630. The D-FF 630 takes in the wave form of the 4×5 frequency divided clock at a falling edge of the 5×4 frequency divided clock. When the frequency of the 5×4 frequency divided clock is different from the frequency of the 4×5 frequency divided clock, the logic level of an output is inconstantly “High” or “Low”. Then the D-FF 630 outputs a signal of which logic level is inconstant as a Q output 633. When the logic level of the output is constant, that is, the logic level of the output is always detected as any of “High” or “Low”, the D-FF 630 outputs the logic level detected as any of “High” or “Low” as the Q output 633. In the first embodiment, the wave form of the 4×5 frequency divided clock can be taken in at the falling edge of the 5×4 frequency divided clock, and vice versa. That is, the wave form of the 4×5 frequency divided clock may be taken in at the falling edge of the 5×4 frequency divided clock. In this manner, the D-FF 630 can still detect the difference between the frequencies.

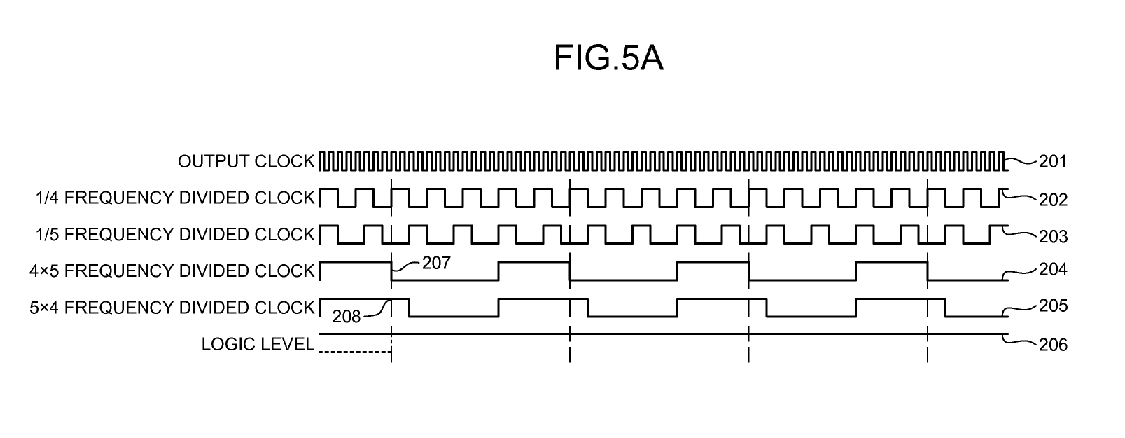

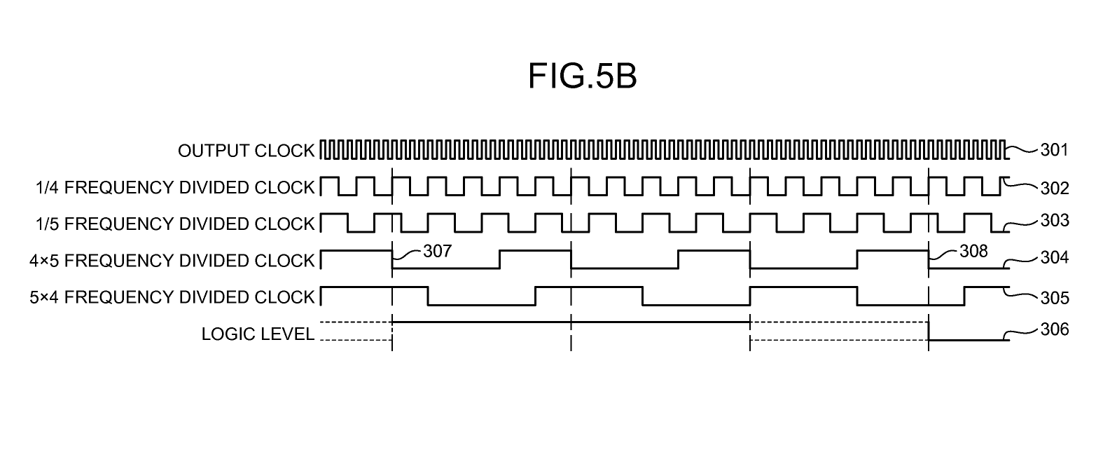

The following describes a state of each clock at the time of normal operation and when malfunction occurs with reference to FIG. 5A and FIG. 5B. FIG. 5A is an example of a timing chart of each clock in a normal operation. FIG. 5B is an example of a timing chart of each clock when malfunction occurs.

In FIG. 5A, a clock 201 is the output clock from the VCO 4. A clock 202 is a frequency divided clock after the output clock is divided by 4 at the ¼ frequency divider 502. A clock 203 is a frequency divided clock after the output clock is divided by 5 at the ⅕ frequency divider 501. A clock 204 is a 4×5 frequency divided clock. A clock 205 is a 5×4 frequency divided clock. A graph 206 represents a logic level determined by the D-FF 630.

At the time of normal operation, the ¼ frequency divider 502 correctly outputs a clock obtained by dividing the output clock by 4, such as the clock 202. The ⅕ frequency divider 501 correctly outputs a clock obtained by dividing the output clock by 5, such as the clock 203. Therefore, the same frequency is shared by the 4×5 frequency divided clock obtained by dividing the output clock by 4, subsequently by 5, and the 5×4 frequency divided clock obtained by dividing the output clock by 5, subsequently by 4, even though the order of division is different. Therefore, in the normal operation, the respective frequencies are the same as represented by the clock 204 and the clock 205 in FIG. 5A. In this case, a falling position of the 4×5 frequency divided clock (for example, a position represented by a dotted line 207) corresponds to a position of the same phase in the 5×4 frequency divided clock. For example, the logic level of the clock 205 at the falling position of the clock 204 is always “High” as indicated by a dot 208 that is an intersection point with the dotted line 207 on the clock 205. Accordingly, in a normal operation, the D-FF 630 always outputs “High” as the logic level as illustrated by the graph 206, for example.

In FIG. 5B, a clock 301 is the output clock from the VCO 4. A clock 302 is a frequency divided clock obtained by dividing the output clock by 4 at the ¼ frequency divider 502. A clock 303 is a frequency divided clock obtained by dividing the output clock by 5 at the ⅕ frequency divider 501. A clock 304 is the 4×5 frequency divided clock. A clock 305 is the 5×4 frequency divided clock. A graph 306 represents a logic level determined by the D-FF 630.

In contrast, malfunction occurs when a clock higher than the upper limit of the operating frequency of the ⅕ frequency divider 501 is input to the ⅕ frequency divider 501. Therefore, when malfunction occurs, the ¼ frequency divider 502 correctly outputs a clock obtained by dividing the output clock by 4 as illustrated by the clock 302. In contrast, it is difficult for the ⅕ frequency divider 501 to correctly output a clock obtained by dividing the output clock by 4 as illustrated by the clock 303. Therefore, the frequency of the 4×5 frequency divided clock obtained by dividing the output clock by 4 and subsequently by 5 is different from the frequency of the 5×4 frequency divided clock obtained by dividing the output clock by 5 and subsequently by 4. Thus, when malfunction occurs, the frequencies are different as illustrated by the clock 304 and the clock 305 in FIG. 5B. Accordingly, the falling position of the 4×5 frequency divided clock (for example, a position represented by a dotted line 307 and a point 308) may correspond to a different phase position in the 5×4 frequency divided clock in some cases. Thus, for example, the logic level of the clock 305 at the falling position of the clock 304 may be “High” as illustrated by the point 308 that is an intersection point with the dotted line 307 on the clock 305. The logic level of the clock 305 may be “Low” in some cases as illustrated by the dot 208 that is the intersection point with the dotted line 307 on the clock 305. For example, when the malfunction occurs, the D-FF 630 outputs the logic level in which “High” and “Low” are mixed as illustrated by the graph 306.

The frequency detector 63 determines from the output of the D-FF 630 whether malfunction is occurring. That is, the frequency detector 63 determines that malfunction is occurring when the logic level of the output from the D-FF 630 is inconstant. The frequency detector 63 determines that malfunction is not occurring when the logic level of the output from the D-FF 630 is constant. Then the frequency detector 63 outputs the determination result to the control unit 7.

The lock detector 8 receives an input of the frequency divided clock and the reference clock output from the frequency divider 5. The lock detector 8 determines an unlocked state when the phases and the frequencies of the frequency divided clock and the reference clock do not match. Then the lock detector 8 notifies the control unit 7 of the unlocked state. The lock detector 8 determines a locked state when the phases and the frequencies of the frequency divided clock and the reference clock match. Then the lock detector 8 notifies the control unit 7 of the locked state.

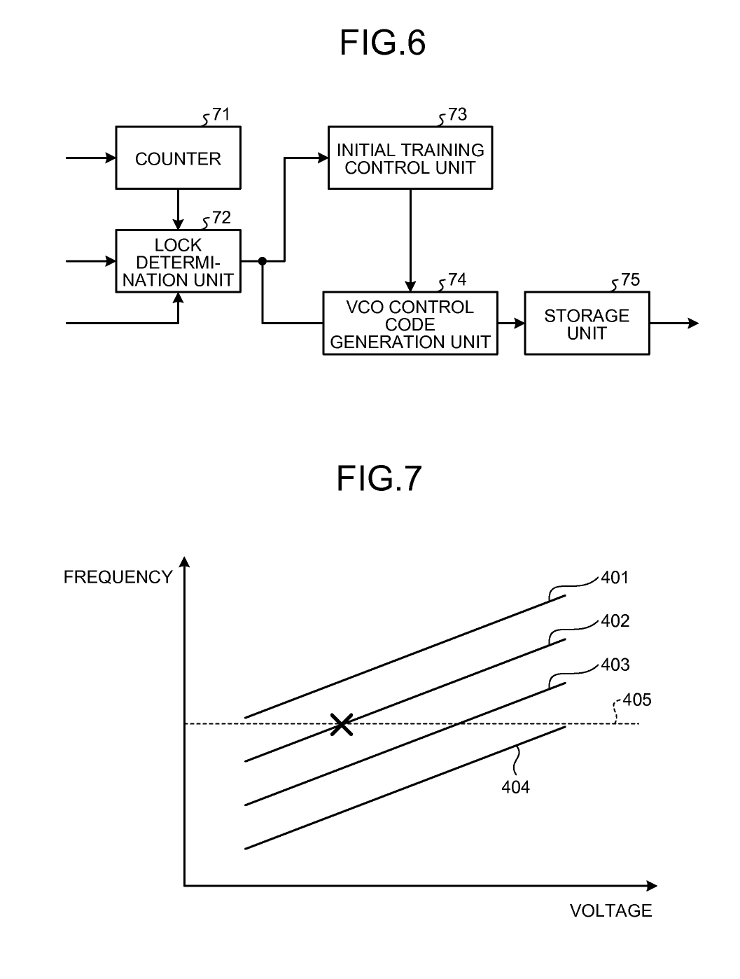

FIG. 6 is a block diagram illustrating the control unit according to the first embodiment. As illustrated in FIG. 6, the control unit 7 includes a counter 71, a lock determination unit 72, an initial training control unit 73, a VCO control code generation unit 74, and a storage unit 75. The control unit 7 is an example of a “control circuit”.

The counter 71 receives an input of the reference clock. Then the counter 71 outputs a signal in synchronization with the frequency of the reference clock to the lock determination unit 72.

The lock determination unit 72 receives a lock detection result and an input of the frequency divided clock from the lock detector 8. When the lock detection result is the unlocked state, the lock determination unit 72 receives information about whether the frequency divided clock is higher or lower than the reference clock from the lock detector 8. The lock determination unit 72 receives an input of a signal in synchronization with the frequency of the reference clock from the counter 71. In addition, the lock determination unit 72 receives a detection result of erroneous frequency division, that is, the determination result of whether malfunction is occurring, from the erroneous frequency division detector 6.

When the lock detection result received from the lock detector 8 is the locked state, the lock determination unit 72 determines whether the output clock is stabilized by determining whether the frequency divided clock is synchronized with a synchronizing signal input from the counter 71. When determining that the output clock is stabilized, the lock determination unit 72 determines whether malfunction is occurring in the result of erroneous frequency division received from the erroneous frequency division detector 6. When malfunction is occurring, the lock determination unit 72 determines the unlocked state and notifies the initial training control unit 73 of the unlocked state. In this case, the lock determination unit 72 also notifies the initial training control unit 73 that malfunction occurs. In contrast, when malfunction is not occurring in the result of erroneous frequency division, the lock determination unit 72 notifies the initial training control unit 73 of the locked state.

When the lock detection result received from the lock detector 8 is the unlocked state, the lock determination unit 72 notifies the initial training control unit 73 of the unlocked state. In this case, the lock determination unit 72 also notifies the initial training control unit 73 of information about whether the frequency divided clock is higher or lower than the reference clock.

For example, the initial training control unit 73 stores correspondence between the control code that controls the oscillation frequency of the VCO 4 and the frequency offset. The following describes a case where the control code is a 2-bit binary code. For example, the initial training control unit 73 stores codes “00”, “01”, “10”, and “11” corresponding to the frequency offsets descending in this order. At the time of activation of the clock generation circuit, for example, the initial training control unit 73 instructs the VCO control code generation unit 74 to generate a binary code that controls the VCO 4 so as to use a middle value of the frequency offsets among the stored correspondence between the binary codes and the oscillation frequencies. In a case of 2-bit binary code, for example, the initial training control unit 73 instructs the VCO control code generation unit 74 to generate the code “01” at the time of activation of the clock generation circuit.

After the clock generation circuit is activated, the initial training control unit 73 receives an input of a result indicating the locked state or the unlocked state from the lock determination unit 72. In a case of the unlocked state, the initial training control unit 73 receives an input of information about the detection of malfunction or about whether the frequency divided clock is higher or lower than the reference clock from the lock determination unit 72.

When receiving a notification of the unlocked state and information about detection of malfunction from the lock determination unit 72, the initial training control unit 73 instructs the VCO control code generation unit 74 to generate a binary code that lowers the frequency offset by one step. When receiving the notification of the unlocked state and information about whether the frequency divided clock is higher or lower than the reference clock, the initial training control unit 73 determines whether a change in frequency offset is executed. When a change in frequency offset is executed, the initial training control unit 73 instructs the VCO control code generation unit 74 to generate a binary code that changes the frequency offset according to whether the received frequency is high or low. For example, when the frequency divided clock is lower than the reference clock, the initial training control unit 73 instructs the VCO control code generation unit 74 to generate a binary code that raises the frequency offset by one step.

When receiving a notification of the locked state from the lock determination unit 72, the initial training control unit 73 finishes the initial training.

In the first embodiment, the initial training control unit 73 controls the VCO 4 by a control code providing a frequency offset having a middle value of the frequency offsets, and subsequently, adjusts the frequency offset. Alternatively, other methods may be employed. For example, the initial training control unit 73 may control the VCO 4 to have a reference oscillation frequency so as to provide the lowest frequency offset, and thereafter, may control to gradually raise the frequency offset.

In the first embodiment, the initial training control unit 73 controls the oscillation frequency based on whether the frequency of the frequency divided clock is higher or lower than the reference clock detected by the lock detector 8. Alternatively, other methods may be employed. For example, the initial training control unit 73 may calculate a difference in frequencies by receiving only information about the unlocked state, and further by receiving the input of the reference clock and the frequency divided clock. The initial training control unit 73 may receive information about whether the frequency becomes higher or lower from the LPF 3 to control the frequency offset of the VCO 4 on the basis of the information.

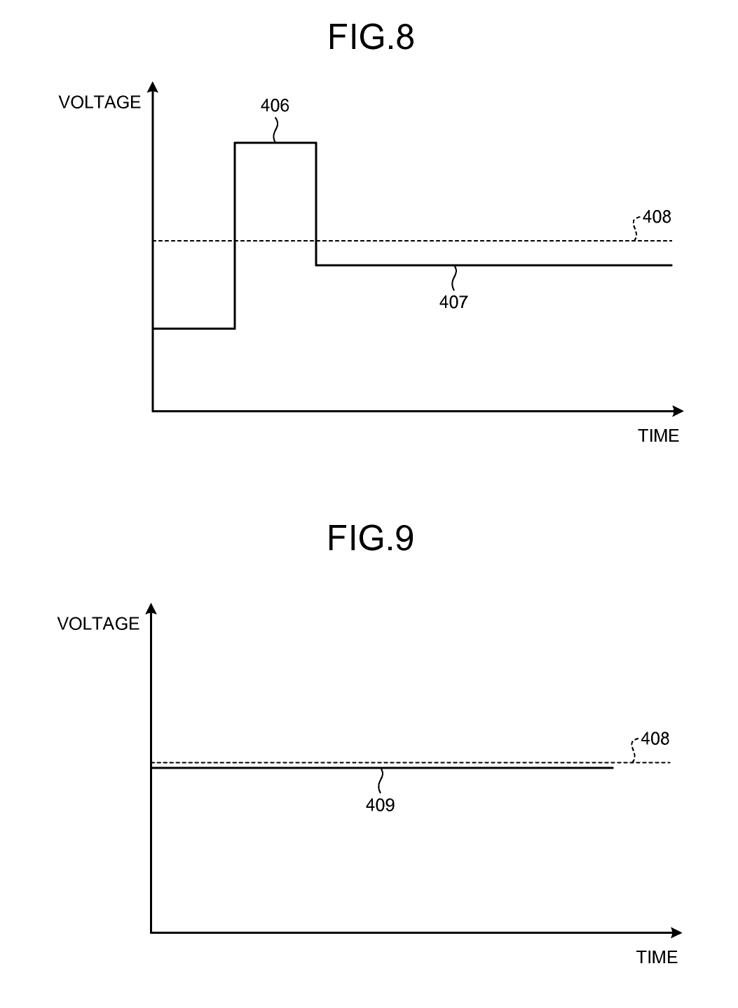

Adjustment of the frequency offset will be described with reference to FIGS. 7 to 9. FIG. 7 is a diagram illustrating a range of frequency adjustment by the VCO for each frequency offset. FIG. 8 is a diagram illustrating adjustment of the oscillation frequency by changing the frequency offset in a normal operation. FIG. 9 is a diagram illustrating the adjustment of the oscillation frequency by changing the frequency offset when malfunction occurs.

In FIG. 7, the horizontal axis represents the voltage and the vertical axis represents the frequency. In FIG. 8 and FIG. 9, the vertical axis represents the voltage and the horizontal axis represents time.

In FIG. 7, a line 401 represents adjustment of the frequency by the VCO 4 when the code “00” is provided. A line 402 represents adjustment of the frequency by the VCO 4 when the code “01” is provided. A line 403 represents adjustment of the frequency by the VCO 4 when the code “10” is provided. A line 404 represents adjustment of the frequency by the VCO 4 when the code “11” is provided. A dotted line 405 represents the frequency of the output clock of which frequency divided clock matches the reference clock (herein, referred to as an “adjusted value”). That is, the VCO 4 controls the output clock to agree with the dotted line 405. For example, as represented by the line 401, the oscillation frequency that the VCO 4 can output may become higher than the adjusted value in some cases depending on the frequency offset. In this case, it is difficult for the VCO 4 to control an output frequency so as to agree with the adjusted value. Therefore, for example, the initial training control unit 73 performs control to lower the frequency offset. Specifically, when the code “00” is used, the initial training control unit 73 performs control to use the code “01”.

A dotted line 408 in FIG. 8 represents a threshold voltage. For example, as illustrated in FIG. 8, it is assumed that voltage exceeds the threshold voltage as illustrated by a voltage 406 when the VCO 4 is controlled using the code “00”. When the voltage applied to the VCO 4 exceeds the threshold voltage, it is difficult for the VCO 4 to cause the oscillation frequency to be close to the adjusted value. Therefore, in this case, the initial training control unit 73 determines that the oscillation frequency of the VCO 4 is high. Then the initial training control unit 73 controls the VCO 4 using the code “01” that lowers an adjusting offset by one step. In this case, the voltage falls below the threshold voltage as illustrated by a voltage 407. In a normal operation, by repeating procedures as described above, the initial training control unit 73 brings the voltage applied to the VCO 4 close to the middle of a control voltage, and brings the oscillation frequency of the VCO 4 close to the adjusted value.

In contrast, when malfunction occurs, the frequency divided clock of which frequency is lower than an actual frequency is output. In this case, as illustrated by a voltage 409 in FIG. 9, there is a risk that the frequency of the output clock of the VCO 4 when controlled by using the code “00” is recognized to be lower than the threshold voltage represented by the dotted line 408. In this case, the initial training control unit 73 determines that the oscillation frequency of the VCO 4 is low. The code “00” is a code indicating the highest frequency offset, so that a state where the VCO 4 is controlled using the code “00” has a high range limit value. In this case, it is difficult to further increase the voltage applied to the VCO 4, so that the initial training control unit 73 finishes controlling the frequency offset adjustment. Therefore, when malfunction occurs as illustrated in FIG. 9 in the first embodiment, the state illustrated in FIG. 9 is cancelled by detecting malfunction and causing the initial training control unit 73 to control the VCO 4 using a code that lowers the frequency offset by one step, and the state illustrated in FIG. 8 is adjusted again. Accordingly, even if malfunction occurs, the initial training control unit 73 may avoid finishing the control in such a malfunctioning state, and adjust the output clock to an appropriate value.

The VCO control code generation unit 74 is instructed by the initial training control unit 73 to generate the control code. The VCO control code generation unit 74 generates the control code instructed by the initial training control unit 73. Then the VCO control code generation unit 74 causes the storage unit 75 to store therein the generated control code.

The control unit 7 outputs the control code stored in the storage unit 75 to the VCO 4.

When the frequency divided clock is correctly synchronized with the reference clock and the PLL is locked, the control unit 7 finishes the process of initial training. When the initial training is completed, the erroneous frequency division detector 6 may stop the process of detecting malfunction.

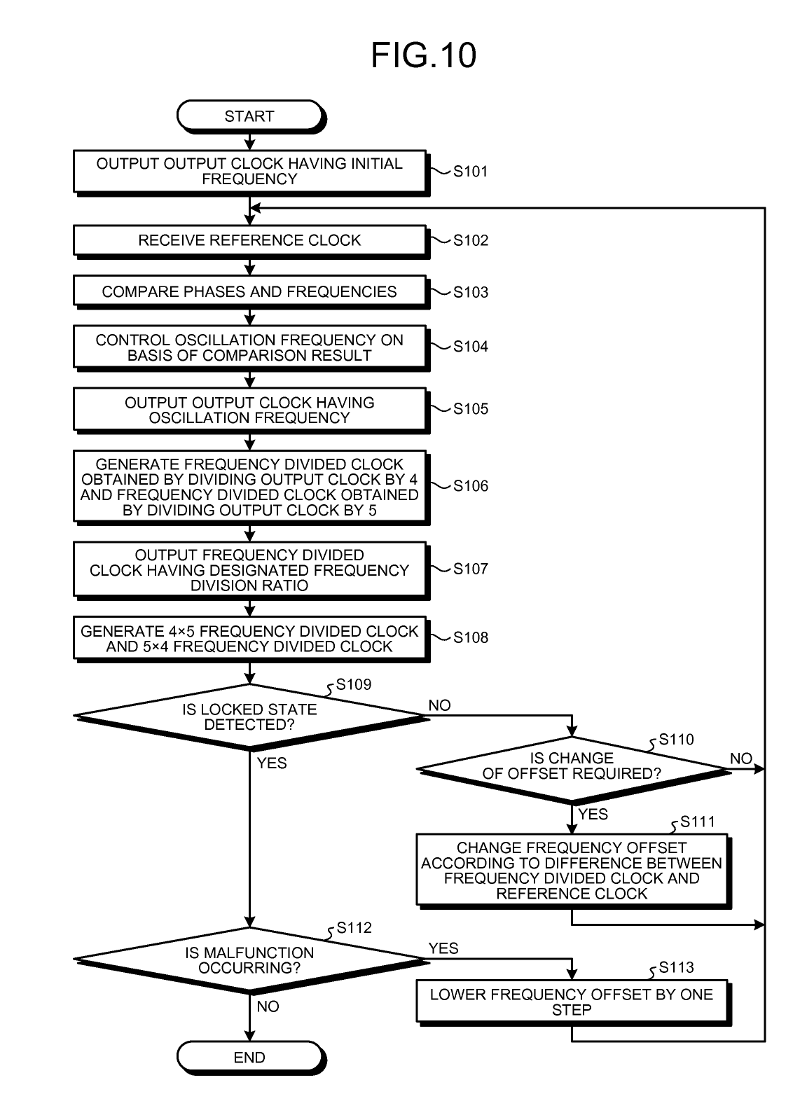

The following describes the process of initial training in the clock generation circuit according to the first embodiment with reference to FIG. 10. FIG. 10 is a flow chart of the process of initial training in the clock generation circuit according to the first embodiment.

The VCO 4 outputs the output clock having an initial frequency (Step S101). The phase frequency director 1 receives a frequency divided clock obtained by dividing the output clock having a free running frequency at a designated frequency division ratio.

The phase frequency director 1 receives the reference clock (Step S102).

The phase frequency director 1 compares the phases and frequencies of the received frequency divided clock and the reference clock (Step S103).

The VCO 4 controls the oscillation frequency according to the comparison result by the phase frequency director 1 (Step S104).

The VCO 4 outputs the output clock having the controlled oscillation frequency (Step S105).

The frequency divider 5 generates a clock obtained by dividing the output clock by 4 at the ¼ frequency divider 502 and generates a clock obtained by dividing the output clock by 5 at the ⅕ frequency divider 501 (Step S106).

The frequency divider 5 also outputs the frequency divided clock having a frequency division ratio designated by the frequency division ratio selection control signal to the phase frequency director 1 (Step S107).

Next, the erroneous frequency division detector 6 receives an input of the clock obtained by dividing the output clock by 4 and the clock obtained by dividing the output clock by 5 from the frequency divider 5. Then the erroneous frequency division detector 6 divides, at the ⅕ frequency divider 602, the clock obtained by dividing the output clock by 4 and generates the 4×5 frequency divided clock. The erroneous frequency division detector 6 divides the clock obtained by dividing the output clock by 5 by the ¼ frequency divider 601 and generates the 5×4 frequency divided clock (Step S108).

The control unit 7 determines whether the locked state is detected (Step S109). When it is determined that the unlocked state is detected (No at Step S109), the control unit 7 determines whether the change of the frequency offset is executed, by using a difference between the frequency divided clock and the reference clock (Step S110). When the control unit 7 determines that the change of the frequency offset is not executed (No at Step S110), the process returns to Step S102. In contrast, when the change of the frequency offset is executed (Yes at Step S110), the control unit 7 changes the frequency offset according to the difference between the frequency divided clock and the reference clock (Step S111), and the process returns to Step S102.

When the locked state is detected (Yes at Step S109), the frequency detector 63 of the erroneous frequency division detector 6 detects a difference between the frequency of the 4×5 frequency divided clock and the frequency of the 5×4 frequency divided clock. Then the frequency detector 63 determines whether malfunction is occurring from a difference between the frequency of the 4×5 frequency divided clock and the frequency of the 5×4 frequency divided clock input from the frequency detector 63 (Step S112). When malfunction is occurring (Yes at Step S112), the control unit 7 performs control to lower the frequency offset of the VCO 4 by one step (Step S113).

In contrast, when malfunction is not occurring (No at Step S112), the control unit 7 finishes the process of initial training.

As described above, the clock generation circuit according to the first embodiment generates the 4×5 frequency divided clock and the 5×4 frequency divided clock by generating a clock obtained by dividing the output clock by an odd number and a clock obtained by dividing the output clock by an even number, and further dividing the generated clocks at the respective frequency division ratios. Then the clock generation circuit according to the first embodiment compares the frequency of the 4×5 frequency divided clock with the frequency of the 5×4 frequency divided clock to detect malfunction of the odd-number frequency divider, and lowers the oscillation frequency of the VCO. Accordingly, even when a clock exceeding the upper limit of the operating frequency is input to the odd-number frequency divider and the output clock is locked in a high state, the clock generation circuit according to the first embodiment can set the clock input to the odd-number frequency divider to a clock below the operating frequency. That is, even when the output clock is locked in a high state, the output clock can be continuously adjusted to be a correct value. Therefore, the clock generation circuit according to the first embodiment can reduce the occurrence of malfunction when pulling in the PLL.

### [b] Second Embodiment

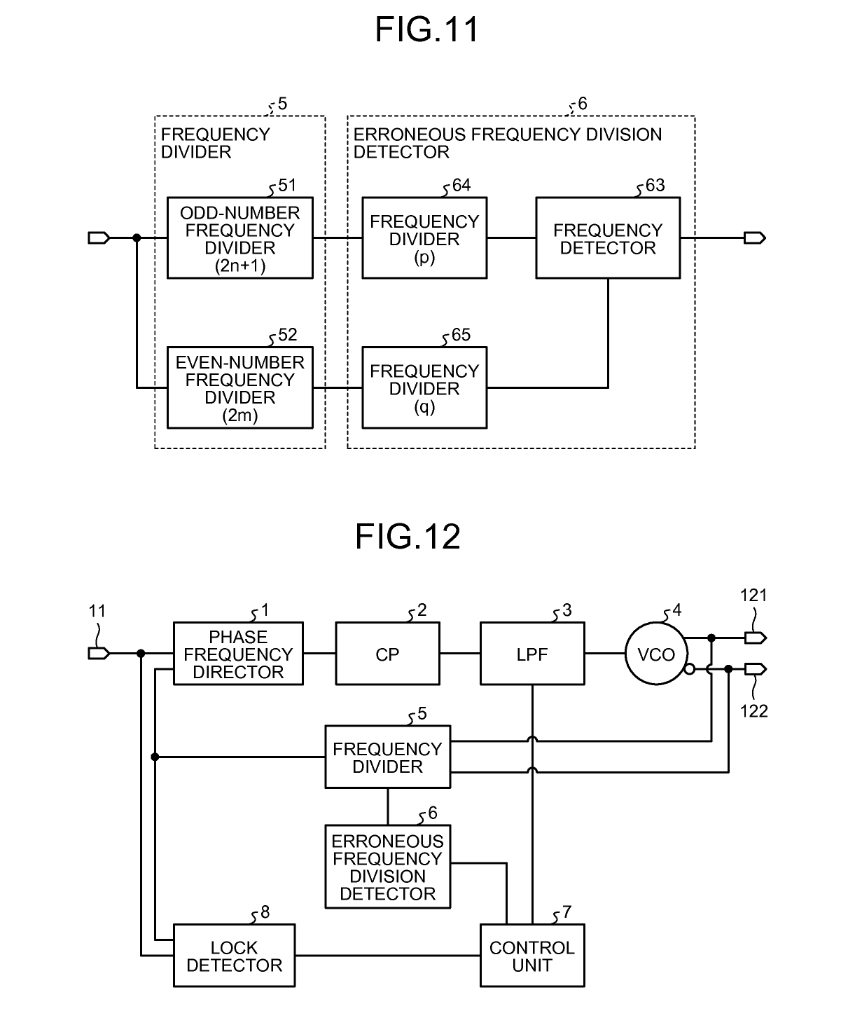

FIG. 11 is a figure of the principle of the frequency divider and the erroneous frequency division detector according to a second embodiment. The clock generation circuit according to the second embodiment is different from that in the first embodiment in that: the frequency division ratio of the odd number frequency divider arranged in the frequency divider is different from the frequency division ratio of the odd number frequency divider arranged in the erroneous frequency division detector; and the frequency division ratio of the even number frequency divider arranged in the frequency divider is different from the frequency division ratio of the even number frequency divider arranged in the erroneous frequency division detector. In the following, the frequency division ratio and the erroneous frequency division detector will be mainly described. The clock generation circuit according to the second embodiment is illustrated in FIG. 1. In the clock generation circuit according to the second embodiment, each component denoted by the same reference numeral as that in the first embodiment has the same function as that in the first embodiment, unless specifically described.

As illustrated in FIG. 11, the frequency divider 5 according to the second embodiment includes the odd-number frequency divider 51 that divides the output clock at the odd number frequency division ratio (2n+1) and the even-number frequency divider 52 that divides the output clock at the even number frequency division ratio (2m). The erroneous frequency division detector 6 includes a frequency divider 64 that divides an input signal by p, a frequency divider 65 that divides an input signal by q, and the frequency detector 63. Herein, p and q are not specifically limited as long as they are positive integers with which the frequency divided clocks input to the frequency detector from the frequency divider 64 and the frequency divider 65 have the same frequency. That is, p and q may be positive integers that satisfy p(2n+1)=q(2m).

The frequency divider 64 receives an input of the frequency divided clock obtained by dividing the output clock by 2n+1 from the odd-number frequency divider 51. Then the frequency divider 64 divides the received frequency divided clock by p to generate the frequency divided clock. That is, the frequency divider 64 generates a clock obtained by dividing the output clock by 2n+1 and further by p. Then the frequency divider 64 outputs the generated frequency divided clock to the frequency detector 63. The frequency divider 64 is an example of the “second frequency divider circuit”.

The frequency divider 65 receives an input of the frequency divided clock obtained by dividing the output clock by 2m from the even-number frequency divider 52. Then the frequency divider 65 divides the received frequency divided clock by q to generate the frequency divided clock. That is, the frequency divider 65 generates a clock obtained by dividing the output clock by 2m and further by q. Then the frequency divider 65 outputs the generated frequency divided clock to the frequency detector 63. the frequency divider 65 is an example of the “fourth frequency divider circuit”.

The frequency detector 63 receives an input of the frequency divided clock generated by the frequency divider 64 and an input of the frequency divided clock generated by the frequency divider 65 from the frequency divider 64 and the frequency divider 65, respectively. Then the frequency detector 63 determines whether the frequency of the frequency divided clock generated by the frequency divider 64 is different from the frequency of the frequency divided clock generated by the frequency divider 65. The frequency detector 63 outputs the determination result to the control unit 7.

As described above, p and q are set so that the frequency divided clocks input to the frequency detector from the frequency divider 64 and the frequency divider 65 have the same frequency. Therefore, the frequencies are match in the normal operation, and the frequency detector 63 outputs a signal indicating that there is no difference between the frequency of the frequency divided clock generated by the frequency divider 64 and the frequency of the frequency divided clock generated by the frequency divider 65 to the control unit 7. In contrast, when malfunction occurs, the frequency of the frequency divided clock generated by the frequency divider 64 and the frequency of the frequency divided clock generated by the frequency divider 65 do not match. In this case, the frequency detector 63 outputs a signal indicating that there is a difference between the frequency of the frequency divided clock generated by the frequency divider 64 and the frequency of the frequency divided clock generated by the frequency divider 65 to the control unit 7. Accordingly, also in the second embodiment, malfunction can be detected as in the first embodiment.

As described above, the clock generation circuit according to the second embodiment has an increased degree of freedom for selecting the frequency divider to be arranged in the erroneous frequency division detector 6. This leads to an increased degree of freedom for designing the erroneous frequency division detector 6.

### [c] Third Embodiment

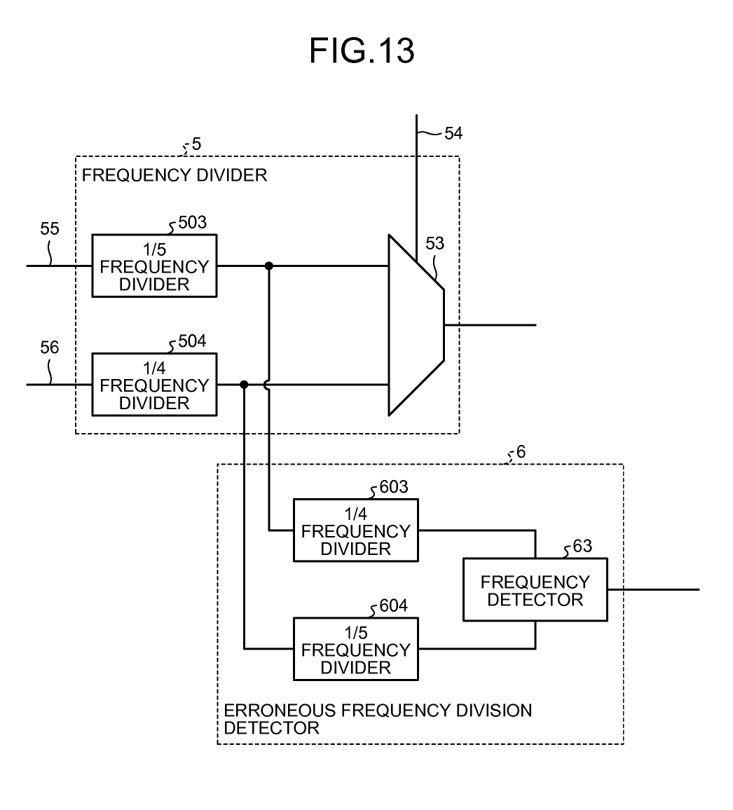

FIG. 12 is a block diagram illustrating the clock generation circuit according to a third embodiment. FIG. 13 is a schematic diagram illustrating the frequency divider and the frequency divider circuit according to the third embodiment. The clock generation circuit according to the third embodiment is different from that in the first embodiment in that the output of the VCO 4 has multiple phases and malfunction is detected using the multiple-phase output. Thus, the frequency division ratio and the erroneous frequency division detector will be mainly described hereinafter. In FIG. 12, each component denoted by the same reference numeral as that in FIG. 1 have the same function as that in FIG. 1, unless specifically described.

As illustrated in FIG. 12, the third embodiment describes a case where the VCO output has two phases. The VCO 4 outputs an output clock that is a normal rotation signal (phase 0°) to an output terminal 121. Then the VCO 4 outputs an output clock that is an inverted signal of which phase difference with respect to the normal rotation signal is 180° to an output terminal 122. The VCO 4 also outputs the output clock that is the normal rotation signal and the output clock that is the inverted signal to the frequency divider 5.

As illustrated in FIG. 13, the frequency divider 5 according to the third embodiment includes a ⅕ frequency divider 503, a ¼ frequency divider 504, and the selector 53. The erroneous frequency division detector 6 includes a ¼ frequency divider 603, a ⅕ frequency divider 604, and the frequency detector 63.

The ⅕ frequency divider 503 receives an input of the output clock that is a normal rotation signal (phase difference 0°) from a line 55. The ⅕ frequency divider 503 generates a clock obtained by dividing the output clock at the frequency division ratio of 5. Then the ⅕ frequency divider 503 outputs the generated clock to the selector 53 and the ¼ frequency divider 603 of the erroneous frequency division detector 6.

The ¼ frequency divider 504 receives an input of the output clock that is an inverted signal (phase difference 180°) from a line 56. The ¼ frequency divider 504 generates a clock obtained by dividing the output clock at the frequency division ratio of 4. Then the ¼ frequency divider 504 outputs the generated clock to the selector 53 and the ⅕ frequency divider 604 of the erroneous frequency division detector 6.

The ¼ frequency divider 603 receives an input of a clock obtained by dividing the output clock that is a normal rotation signal at the frequency division ratio of 5 from the ⅕ frequency divider 503. The ¼ frequency divider 603 divides the received clock at the frequency division ratio of 4 to generate a frequency divided clock (hereinafter, also referred to as a “5×4 frequency divided normal rotation clock” in some cases). Then the ¼ frequency divider 603 outputs the generated 5×4 frequency divided normal rotation clock to the frequency detector 63.

The ⅕ frequency divider 604 receives an input of a clock obtained by dividing the output clock that is an inverted signal at the frequency division ratio of 4 from the ¼ frequency divider 504. The ⅕ frequency divider 604 divides the received clock at the frequency division ratio of 5 to generate a frequency divided clock (hereinafter, also referred to as a “4×5 frequency divided inverted clock” in some cases). Then the ⅕ frequency divider 604 outputs the generated 4×5 frequency divided inverted clock to the frequency detector 63.

The frequency detector 63 receives an input of the 5×4 frequency divided normal rotation clock from the ¼ frequency divider 603. The frequency detector 63 also receives an input of the 4×5 frequency divided inverted clock from the ⅕ frequency divider 604. Then the frequency detector 63 determines whether there is a difference in frequencies from the frequency of the 5×4 frequency divided normal rotation clock at a falling position of the 4×5 frequency divided inverted clock. The frequency detector 63 outputs the determination result to the control unit 7.

As described above, the clock generation circuit according to the third embodiment can detect malfunction using the output clocks having different phases. Accordingly, many more types of signals may be used for detecting malfunction, and the degree of freedom for designing a clock circuit may be increased.

According to an aspect of a clock generation circuit and a method for controlling the clock generation circuit disclosed herein, malfunction can be avoided when pulling in a PLL.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A clock generation circuit comprising:
a phase lock loop (PLL) that generates an output clock obtained by multiplying a reference clock by an odd number of multiplication;
a first frequency divider circuit that divides the output clock by the odd number to generate a first frequency divided clock;
a second frequency divider circuit that divides the first frequency divided clock by a predetermined number to generate a second frequency divided clock;
a third frequency divider circuit that divides the output clock by an even number to generate a third frequency divided clock;
a fourth frequency divider circuit that divides the third frequency divided clock at such a frequency division ratio that makes a frequency division ratio of the first frequency divider circuit and the second frequency divider circuit match a frequency division ratio of the third frequency divider circuit, to generate a fourth frequency divided clock;
a comparator circuit that compares phases or frequencies of the second frequency divided clock and the fourth frequency divided clock; and
a control circuit that performs control of lowering an oscillation frequency of the PLL when the comparison result by the comparator circuit represents a mismatch.

2. The clock generation circuit according to claim 1, wherein
the second frequency divider circuit divides the frequency by the even number, and
the fourth frequency divider circuit divides the frequency by the odd number.

3. The clock generation circuit according to claim 1, wherein the control circuit performs control of lowering an oscillation frequency of a voltage controlled oscillator (VCO) included in the PLL when the comparison result by the comparator circuit represents a mismatch.

4. The clock generation circuit according to claim 3, wherein the control circuit lowers the oscillation frequency of the VCO by lowering a frequency offset of the VCO included in the PLL when the comparison result by the comparator circuit represents a mismatch.

5. The clock generation circuit according to claim 1, wherein the comparator circuit determines the comparison result indicating a mismatch in phases or frequencies on the basis of a logic level of any one of the fourth frequency divided clock and the second frequency divided clock at an edge of the other.

6. The clock generation circuit according to claim 1, further comprising a lock detector that detects that a phase state is in a locked state, wherein
the control circuit performs control of lowering the oscillation frequency of the PLL and pulling in the clock again when the lock detector detects the locked state and the comparison result of the phases or the frequencies of the second frequency divided clock and the fourth frequency divided clock represents a mismatch.

7. The clock generation circuit according to claim 1, wherein
the PLL generates a first output clock and a second output clock having different phases,
the first frequency divider circuit generates the first frequency divided clock from the first output clock, and
the third frequency divider circuit generates the third frequency divided clock from the second output clock.

8. A method for controlling a clock generation circuit, the method comprising:
generating an output clock obtained by multiplying a reference clock by an odd number of multiplication;
dividing the output clock by the odd number to generate a first frequency divided clock;
dividing the first frequency divided clock by a predetermined number to generate a second frequency divided clock;
dividing the output clock by an even number to generate a third frequency divided clock;
dividing the third frequency divided clock to generate a fourth frequency divided clock of which frequency division ratio with respect to the output clock matches a frequency division ratio of the second frequency divided clock with respect to the output clock;
comparing phases or frequencies of the second frequency divided clock and the fourth frequency divided clock; and
lowering an oscillation frequency of a phase lock loop when the comparison result represents a mismatch.

9. A clock generation circuit comprising:
a phase comparator that compares a reference clock and another input clock;
a voltage controlled oscillator (VCO) that changes an oscillation frequency on the basis of the comparison result by the phase comparator and generates an output clock obtained by multiplying the reference clock by an odd number;
a first frequency divider circuit that divides the output clock generated by the VCO by the odd number to generate a first frequency divided clock, and inputs the first frequency divided clock to the phase comparator;
a second frequency divider circuit that divides the first frequency divided clock by a predetermined number to generate a second frequency divided clock;
a third frequency divider circuit that divides the output clock generated by the VCO by an even number to generate a third frequency divided clock;
a fourth frequency divider circuit that divides the third frequency divided clock at such a frequency division ratio that makes a frequency division ratio of the first frequency divider circuit and the second frequency divider circuit match a frequency division ratio of the third frequency divider circuit, to generate a fourth frequency divided clock;
a comparator circuit that compares phases or frequencies of the second frequency divided clock and the fourth frequency divided clock; and
a control circuit that performs control of lowering an oscillation frequency of a phase lock loop when the comparison result by the comparator circuit represents a mismatch.
